(19) United States
(12) Patent Application Publication
(10) Pub. No.: US 2025/0203769 A1
(43) Pub. Date: Jun. 19, 2025

(54) WIRING SUBSTRATE AND MANUFACTURING METHOD THEREOF

(71) Applicant: NICHIA CORPORATION, Anan-shi (JP)

(72) Inventors: Atsushi HOSOKAWA, Tokushima-shi (JP); Akiko NAGAE, Tokushima-shi (JP)

(73) Assignee: NICHIA CORPORATION, Anan-shi (JP)

(21) Appl. No.: 18/983,341

(22) Filed: Dec. 17, 2024

(30) Foreign Application Priority Data
Dec. 19, 2023 (JP) 2023-214191

(51) Int. Cl. H05K 1/03; H05K 1/11; H05K 3/26; H05K 3/28

(52) U.S. Cl. CPC H05K 1/0306; H05K 1/115; H05K 3/26; H05K 3/28

(57) ABSTRACT

A method of manufacturing a wiring substrate includes preparing a ceramic substrate including a ceramic plate having a first recessed portion disposed in a first surface, a second recessed portion disposed in a second surface opposite to the first surface, and a through hole connecting the first recessed portion and the second recessed portion. A metal member is disposed continuously in the first recessed portion, the second recessed portion, and the through hole. The method includes disposing a protective film on a part of the metal member, blasting an other part of the metal member and at least a part of the first surface of the ceramic plate, disposing a covering member in a recessed portion from which the other part of the metal member and the part of the first surface of the ceramic plate have been removed by the blasting, and removing the protective film.

### CROSS-REFERENCE TO RELATED APPLICATIONS

The present application claims priority under 35 U.S.C. § 119 to Japanese Patent Application No. 2023-214191, filed Dec. 19, 2023, the contents of which is hereby incorporated by reference in its entirety.

### BACKGROUND

### 1. Technical Field

The present disclosure relates to a wiring substrate and a manufacturing method thereof.

### 2. Description of Related Art

Ceramic substrates are widely used as wiring substrates for electronic components. For example, Japanese Patent Publication No. H3-004592 describes a method in which wet etching or dry etching is performed on a surface of a ceramic substrate having a via without polishing the ceramic substrate, to form an etched surface, a via protruding from the etched surface is formed, an organic insulating layer is disposed on the etched surface and polished, thereby manufacturing the ceramic substrate having a via on a surface of the organic insulating layer.

In addition, Japanese Patent Publication No. 2015-138934 describes a substrate processing method in which a mask layer is formed on a surface of a substrate made of ceramic or the like, the mask layer on the substrate surface is patterned, the substrate surface exposed without being covered with the mask layer is processed, and a plurality of recessed parts having different depths are formed in the substrate surface by wet etching.

### SUMMARY

Embodiments of the present disclosure can provide a manufacturing method of a wiring substrate that can be easily provided with various electrode patterns and has excellent conductivity, and a wiring substrate having a fine electrode pattern and excellent conductivity.

A manufacturing method of a wiring substrate according to an embodiment of the present disclosure includes preparing a ceramic substrate including a ceramic plate including a first recessed portion disposed in a first surface, a second recessed portion disposed in a second surface opposite to the first surface, and a through hole connecting the first recessed portion and the second recessed portion, and a metal member disposed continuously in the first recessed portion, the second recessed portion, and the through hole; disposing a protective film on a part of at least the metal member of the ceramic substrate; blasting the other part of the metal member other than the part of the metal member provided with the protective film and at least a part of the first surface of the ceramic plate; disposing a covering member in a recessed portion from which the other part of the metal member and at least the part of the first surface of the ceramic plate have been removed by the blasting; and removing the protective film.

A wiring substrate according to an embodiment of the present disclosure includes a ceramic substrate including a ceramic plate including a first recessed portion disposed in a first surface, a second recessed portion disposed in a second surface opposite to the first surface, and a through hole connecting the first recessed portion and the second recessed portion, and a metal member disposed continuously in the first recessed portion, the second recessed portion, and the through hole and including a protruding portion having an upper surface on a side of the first surface, the upper surface protruding with respect to the first surface; and a covering member being in contact with the other part of an upper surface of the metal member other than the upper surface of the protruding portion and at least a part of the first surface of the ceramic plate, in which a surface roughness Ra of the other part of the upper surface of the metal member and at least a part of the first surface of the ceramic plate is equal to or greater than 350 nm.

An embodiment of the present disclosure can provide a manufacturing method of a wiring substrate that can be easily provided with various electrode patterns and has excellent conductivity, and a wiring substrate having a fine electrode pattern and excellent conductivity.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1A is a schematic plan view illustrating an example of a first surface of a wiring substrate according to an embodiment.

FIG. 1B is a schematic cross-sectional view taken along line IB-IB in FIG. 1A.

FIG. 1C is a schematic explanatory view illustrating only a ceramic plate in FIG. 1B.

FIG. 2 is a schematic enlarged view of a region II in FIG. 1B.

FIG. 3A is a flowchart showing an example of a manufacturing method of a wiring substrate according to an embodiment.

FIG. 3B is a flowchart showing an example of preparing of a ceramic substrate in a manufacturing method of a wiring substrate according to an embodiment.

FIG. 4A is a schematic cross-sectional view illustrating preparing of a ceramic substrate.

FIG. 4B is a schematic cross-sectional view illustrating disposing of a protective film.

FIG. 4C is a schematic cross-sectional view illustrating performing blasting.

FIG. 4D is a schematic cross-sectional view illustrating disposing of a covering member.

FIG. 4E is a schematic cross-sectional view illustrating removing of a protective film.

FIG. 5A is a schematic cross-sectional view illustrating preparing of a ceramic plate in preparing of a ceramic substrate.

FIG. 5B is a schematic cross-sectional view illustrating disposing of a protective film in preparing of a ceramic substrate.

FIG. 5C is a schematic cross-sectional view illustrating forming of a through hole in preparing of a ceramic substrate.

FIG. 5D is a schematic cross-sectional view illustrating removing of a protective film in preparing of a ceramic substrate.

FIG. 5E is a schematic cross-sectional view illustrating performing filling with a metal paste in preparing of a ceramic substrate.

FIG. 5F is a schematic cross-sectional view illustrating firing of a metal paste in preparing of a ceramic substrate.

FIG. 5G is a schematic cross-sectional view illustrating performing polishing or grinding in preparing of a ceramic substrate.

FIG. 6A is an enlarged cross-sectional view schematically illustrating a state of a ceramic plate on which a metal paste is disposed in preparing of a ceramic substrate.

FIG. 6B is an enlarged cross-sectional view schematically illustrating a state of a metal member after the ceramic plate on which the metal paste in FIG. 6A is disposed is sintered.

FIG. 7A is a schematic plan view illustrating an example of a shape pattern of a protective portion in a protective film used on a first surface of a ceramic substrate in disposing of a protective film.

FIG. 7B is a schematic plan view illustrating an example of a shape pattern of a protective portion in a protective film used on a second surface of a ceramic substrate in disposing of a protective film.

FIG. 8A is a schematic enlarged view of a metal member in plan view of a wiring substrate produced using a region VIIIA of the protective film illustrated in FIG. 7A.

FIG. 8B is a schematic cross-sectional view of a wiring substrate taken along line VIIIB-VIIIB in FIG. 8A.

FIG. 8C is a schematic cross-sectional view of a wiring substrate taken along line VIIIC-VIIIC in FIG. 8A.

FIG. 9A is a schematic enlarged view of a metal member in plan view of a wiring substrate produced using a region VIIIIA of the protective film illustrated in FIG. 7A.

FIG. 9B is a schematic cross-sectional view of a wiring substrate taken along line VIIIIB-VIIIIB in FIG. 9A.

FIG. 9C is a schematic cross-sectional view of a wiring substrate taken along line VIIIIC-VIIIIC in FIG. 9A.

### DETAILED DESCRIPTION OF EMBODIMENT

### Description of Embodiments

Hereinafter, a substrate of an embodiment according to the present invention (hereinafter, may be referred to as a “wiring substrate according to an embodiment”) and a manufacturing method of a wiring substrate (hereinafter, may be referred to as a “manufacturing method of a wiring substrate according to an embodiment”) are described with reference to the drawings. Note that, in the following description, terms indicating specific directions or positions (for example, “upper”, “lower”, and other terms including those terms) are used as necessary. The use of those terms, however, is to facilitate understanding of the invention with reference to the drawings, and the technical scope of the present invention is not limited by the meanings of those terms. Parts or members having the same reference characters appearing in a plurality of drawings indicate identical or equivalent parts or members.

The following embodiments exemplify a wiring substrate and a manufacturing method of a wiring substrate for embodying a technical concept of the present invention, and the present invention is not limited to the description below. The dimensions, materials, shapes, relative arrangements, and the like of parts or members described below are not intended to limit the scope of the present invention to those alone, but are intended to provide an example, unless otherwise specified. The contents described in one embodiment can be applied to the other embodiments and modified examples. The dimensions, positional relationship, and the like of parts or members illustrated in the drawings can be exaggerated in order to clarify the explanation. Moreover, in order to avoid excessive complication of the drawings, a schematic view in which some parts or members are not illustrated may be used, or an end view illustrating only a cutting surface may be used as a cross-sectional view. Furthermore, “disposing” includes not only a case of disposing by direct contact but also a case of indirectly disposing, for example, via another member.

In the wiring substrate and the manufacturing method of the wiring substrate according to an embodiment, a first surface of a wiring substrate 200 provided with a covering member 4 is referred to as a “front surface” used for electrically connecting to electrodes of a light-emitting element, and a second surface of the wiring substrate 200 opposite to the first surface is referred to as a “back surface” used for electrically connecting to electrodes of a mounting substrate. In the drawings related to the wiring substrate and the manufacturing method of the wiring substrate according to an embodiment, unless otherwise stated, the first surface of the wiring substrate 200 is illustrated on an upper side of the drawing, and the second surface of the wiring substrate 200 is illustrated on a lower side of the drawing.

In the wiring substrate and the manufacturing method of the wiring substrate according to an embodiment, a “ceramic plate 1” indicates a member made of only ceramic in a state in which a metal member 2 is not provided.

In the wiring substrate and the manufacturing method of the wiring substrate according to an embodiment, a “ceramic substrate 100” indicates a member in a state in which the metal member 2 is provided on the ceramic plate 1.

In the manufacturing method of the wiring substrate according to an embodiment, the “wiring substrate 200” indicates a final form including the ceramic plate 1, the metal member 2, and the covering member 4.

### Wiring Substrate

The wiring substrate according to an embodiment includes a ceramic substrate including a ceramic plate having a first recessed portion disposed in a first surface, a second recessed portion disposed in a second surface opposite to the first surface, and a through hole connecting the first recessed portion and the second recessed portion, and a metal member disposed continuously in the first recessed portion, the second recessed portion, and the through hole and having a protruding portion whose upper surface on the first surface side protrudes with respect to the first surface; and a covering member disposed in contact with the other part of the upper surface of the metal member other than the upper surface of the protruding portion and at least a part of the first surface of the ceramic plate. The wiring substrate further includes other members as necessary. A surface roughness Ra of the other part of the upper surface of the metal member and at least a part of the first surface of the ceramic plate is equal to or greater than 350 nm.

The wiring substrate according to an embodiment is suitably manufactured by the manufacturing method of the wiring substrate according to an embodiment.

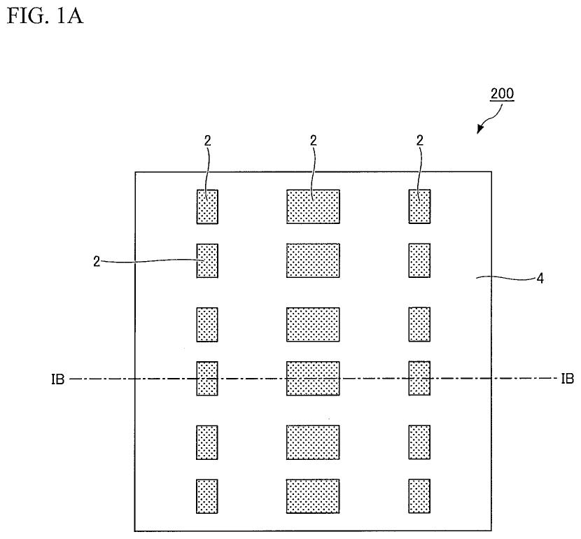

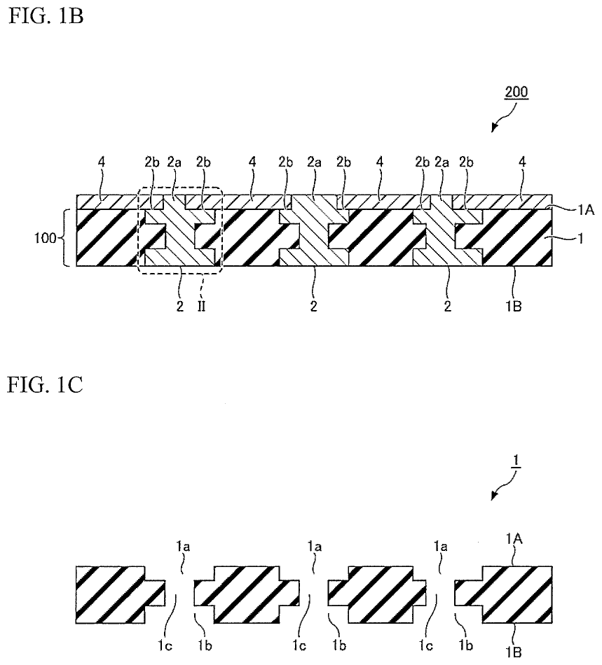

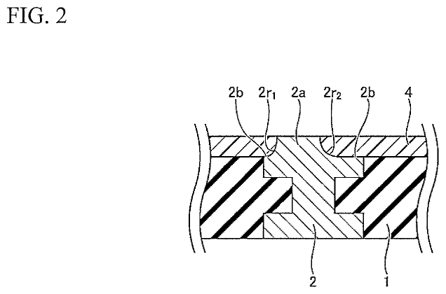

FIG. 1A is a schematic plan view illustrating an example of the first surface of the wiring substrate according to an embodiment. FIG. 1B is a schematic cross-sectional view taken along line IB-IB in FIG. 1A. FIG. 1C is a schematic explanatory view illustrating only the ceramic plate in FIG. 1B. FIG. 2 is a schematic enlarged view of a region II in FIG. 1B.

The wiring substrate 200 according to an embodiment includes the ceramic substrate 100 and the covering member 4.

### Ceramic Substrate

The ceramic substrate 100 includes the ceramic plate 1 and the metal member 2.

### Ceramic Plate

As illustrated in FIGS. 1B and 1C, the ceramic substrate 100 includes a first recessed portion 1a disposed in a first surface 1A of the ceramic plate 1, a second recessed portion 1b disposed in a second surface 1B opposite to the first surface 1A of the ceramic plate 1, and a through hole 1c connecting the first recessed portion and the second recessed portion.

The material of the ceramic plate 1 is not particularly limited, and examples thereof include nitride-based ceramic such as silicon nitride, aluminum nitride, and boron nitride; oxide-based ceramic such as aluminum oxide, silicon oxide, calcium oxide, and magnesium oxide; silicon carbide; mullite; and borosilicate glass. Any of these can be used alone or in combination of two or more. Among these materials, the ceramic is preferably a nitride-based ceramic from the viewpoint of thermal conductivity.

The ceramic plate 1 is a sintered ceramic plate.

The thickness of the ceramic plate 1 is not particularly limited, and is preferably in a range from 50 μm to 500 μm, more preferably in a range from 80 μm to 400 μm.

The plan view shape of the first recessed portion 1a and the bottom view shape of the second recessed portion 1b are not particularly limited, and examples thereof include polygons such as a triangle, a quadrangle, a pentagon, and a hexagon, a circle, and an ellipse. The shape can be a combination of these shapes. The bottom view shape of the second recessed portion 1b is preferably similar to or identical to the shape of the electrodes on the mounting substrate side.

In the ceramic plate 1, the maximum diameter of the first recessed portion 1a in the first surface 1A of the ceramic plate 1 in the plan view direction is not particularly limited and can be appropriately selected according to the electrodes of the light-emitting element, and is preferably in a range from 10 μm to 10 mm, more preferably in a range from 50 μm to 5 mm.

In the ceramic plate 1, the area of the first recessed portion 1a in the first surface 1A of the ceramic plate 1 in the plan view direction is not particularly limited and can be appropriately selected according to the electrodes of the light-emitting element, and is preferably in a range from 100 μm² to 100 mm², more preferably in a range from 2500 μm² to 25 mm². The area of the first recessed portion 1a of the ceramic plate 1 in the plan view direction is the maximum area of an exposed surface of the metal member 2 in the first surface 1A.

In the ceramic plate 1, the maximum diameter of the second recessed portion 1b in the second surface 1B of the ceramic plate 1 in the plan view direction is not particularly limited and can be appropriately selected according to the electrodes of the light-emitting element, and is preferably in a range from 30 μm to 10 mm, more preferably in a range from 50 μm to 5 mm.

In the ceramic plate 1, the area of the second recessed portion 1b in the second surface 1B of the ceramic plate 1 in the plan view direction is not particularly limited, and is preferably in a range from 100 μm² to 100 mm², more preferably in a range from 2500 μm² to 25 mm². The area of the second recessed portion 1b of the ceramic plate 1 in the plan view direction is the maximum area of the exposed surface of the metal member 2.

The first recessed portion 1a is recessed from the first surface 1A of the ceramic plate 1 and refers to a region from an opening portion in the first surface 1A to an end portion of a through hole 1c on the first surface 1A side in a cross-sectional view in the thickness direction of the ceramic plate 1. The number of first recessed portions 1a in the ceramic substrate 100 is not particularly limited, but is preferably plural.

The second recessed portion 1b is recessed from the second surface 1B of the ceramic plate 1, and refers to a region from an opening portion in the second surface 1B to an end portion of a through hole 1c on the second surface 1B side in the cross-sectional view in the thickness direction of the ceramic plate 1. The number of second recessed portions 1b in the ceramic substrate 100 is not particularly limited, but is preferably plural. The number of second recessed portions 1b in the ceramic substrate 100 is the same as the number of first recessed portions 1a in the ceramic substrate 100.

The through hole 1c is a region connecting the first recessed portion 1a and the second recessed portion 1b. That is, in the cross-sectional view in the thickness direction of the ceramic plate 1, the through hole 1c refers to a region from the end portion of the through hole 1c on the first surface 1A side to the end portion of the through hole 1c on the second surface 1B side. The number of through holes 1c in the ceramic substrate 100 is not particularly limited, but is preferably plural. The number of through holes 1c in the ceramic substrate 100 is the same as the number of first recessed portions 1a and the number of second recessed portions 1b in the ceramic substrate 100.

The average depth of the first recessed portion 1a and the average depth of the second recessed portion 1b are not particularly limited, but are each preferably in a range from 1/10 to ⅖, more preferably in a range from ⅕ to ¼ with respect to the thickness of the ceramic plate 1.

The depth of the first recessed portion 1a means a distance from the opening portion of the first recessed portion 1a in the first surface 1A of the ceramic plate 1 to the end portion of the through hole 1c on the first surface 1A side in the cross-sectional view in the thickness direction of the ceramic plate 1. In addition, the average depth of the first recessed portion 1a means an average value of three points arbitrarily selected with respect to the depth of the first recessed portion 1a. In addition, the average depth of the first recessed portion 1a satisfies the following equation: [the thickness of the ceramic plate 1—the average depth of the second recessed portion 1b—the average length of the through hole 1c].

The depth of the second recessed portion 1b means a distance from the opening portion of the second recessed portion 1b in the second surface 1B of the ceramic plate 1 to the end portion of the through hole 1c on the second surface 1B side in the cross-sectional view in the thickness direction of the ceramic plate 1. In addition, the average depth of the second recessed portion 1b means an average value of three points arbitrarily selected with respect to the depth of the second recessed portion 1b. In addition, the average depth of the second recessed portion 1b satisfies the following equation: [the thickness of the ceramic plate 1—the average depth of the first recessed portion 1a—the average length of the through hole 1c].

The plan view shape of the through hole 1c is not particularly limited, and examples thereof include polygons such as a triangle, a quadrangle, a pentagon, and a hexagon, a circle, and an ellipse. The shape can be a combination of these shapes. Among the shapes, a circle is preferable.

In the ceramic plate 1, the maximum diameter of the through hole 1c in the plan view direction is not particularly limited, but is preferably in a range from 20 μm to 500 μm, more preferably in a range from 40 μm to 300 μm.

In the ceramic plate 1, the area of the through hole 1c in the plan view direction is not particularly limited, but is preferably in a range from 400 μm² to 0.25 mm², more preferably in a range from 1600 μm² to 0.09 mm².

In the ceramic plate 1, the area or the maximum diameter of at least one of the first recessed portion 1a and the second recessed portion 1b in the plan view direction can be the same as the area or the maximum diameter of the through hole 1c, can be greater than the area or the maximum diameter of the through hole 1c, or can be smaller than the area or the maximum diameter of the through hole 1c, but is preferably greater than the area or the maximum diameter of the through hole 1c, and more preferably, the area or the maximum diameter of the first recessed portion 1a is greater than the area or the maximum diameter of the through hole 1c. Thus, the area or the maximum diameter in the plan view direction of the metal member 2 disposed in the first recessed portion 1a, that is, the area or the maximum diameter of the exposed surface of the metal member 2 in the first surface 1A of the ceramic plate 1 is greater than the area or the maximum diameter in the plan view direction of the metal member 2 disposed in the through hole 1c.

The length of the through hole 1c is not particularly limited, and can be appropriately selected according to the thickness of the ceramic plate 1, the depth of the first recessed portion 1a, and the depth of the second recessed portion 1b. The length of the through hole 1c means a distance from a bottom portion of the first recessed portion 1a to a bottom portion of the second recessed portion 1b in the cross-sectional view in the thickness direction of the ceramic plate 1. In addition, the average length of the through hole 1c means an average value of three points arbitrarily selected with respect to the length of the through hole 1c. In addition, the average length of the through hole 1c satisfies the following equation: [the thickness of the ceramic plate 1—the average depth of the first recessed portion 1a—the average depth of the second recessed portion 1b].

In the ceramic plate 1, when the first recessed portion 1a, the second recessed portion 1b, and the through hole 1c have the same shape and area in the plan view direction, each of the first recessed portion 1a, the second recessed portion 1b, and the through hole 1c has ⅓ a depth in the plan view direction of the ceramic plate 1. In this case, in the ceramic plate 1, the first recessed portion 1a, the second recessed portion 1b, and the through hole 1c are integrated to form a through hole.

The surface roughness Ra of at least a part of the first surface 1A of the ceramic plate 1 is not particularly limited, but is preferably 350 nm or more, more preferably 500 nm or more. The surface roughness Ra can be measured in accordance with JIS B 0601:2013 by using a stylus type surface roughness measuring instrument (for example, Surfcorder SE 3500 manufactured by Kosaka Laboratory Ltd.) including a diamond stylus with a tip radius r of curvature of 2 μm. The “at least a part of the first surface 1A of the ceramic plate 1” having such a surface roughness Ra refers to a region of the first surface 1A of the ceramic plate 1 that is in contact with the covering member 4. Setting the surface roughness Ra of at least a part of the first surface 1A of the ceramic plate 1 to equal to or greater than 350 nm can be implemented by forming at least a part of the first surface 1A of the ceramic plate 1 by blasting in manufacturing the wiring substrate 200.

The surface roughness Ra of the other part of at least a part of the first surface 1A of the ceramic plate 1 is not particularly limited, but is preferably in a range from 10 nm to 300 nm, more preferably in a range from 30 nm to 200 nm. “The other part other than at least a part of the first surface 1A of the ceramic plate 1” having such a surface roughness Ra is a region of the first surface 1A of the ceramic plate 1 that is not in contact with the covering member 4, and is preferably a region of the first surface 1A of the ceramic plate 1 that is flush with the upper surface of a protruding portion 2a of the metal member 2. Setting the surface roughness Ra of the other part other than at least a part of the first surface 1A of the ceramic plate 1 in a range from 10 nm to 300 nm can be implemented by disposing a protective film on the other part other than at least a part of the first surface 1A of the ceramic plate 1 so that the other part is not subjected to blasting in manufacturing the wiring substrate 200.

### Metal Member

As illustrated in FIGS. 1B and 1C, the metal member 2 includes the protruding portion 2a disposed continuously in the first recessed portion 1a, the second recessed portion 1b, and the through hole 1c and having an upper surface on the first surface 1A side protruding with respect to the first surface 1A.

The metal member 2 is not particularly limited as long as the metal member 2 is a member including a metal, but preferably includes a metal, a metal compound, and an inorganic filler. Thus, the linear expansion coefficients of the metal member 2 and the ceramic plate 1 can be made close to each other, and the likelihood of peeling between the metal member 2 and the ceramic plate 1 can be reduced. The components of the metal member 2 are described in detail below in the section referred to as “Manufacturing Method of Wiring Substrate”.

The shape, structure, and dimensions of the protruding portion 2a of the metal member 2 are not particularly limited, but the area of the upper surface of the protruding portion 2a of the metal member 2 is preferably smaller than the area of a lower surface of the protruding portion 2a. The lower surface of the protruding portion 2a refers to a lower surface of the metal member 2 disposed on the first recessed portion 1a side when cutting is performed in a direction parallel to the plane of the ceramic plate 1 at the boundary between the first recessed portion 1a and the through hole 1c.

In a cross-sectional view in the thickness direction of the wiring substrate 200, the center of gravity of the upper surface of the protruding portion 2a and the center of gravity of the lower surface of the protruding portion 2a can be located at the same position or at different positions. When the center of gravity of the upper surface of the protruding portion 2a and the center of gravity of the lower surface of the protruding portion 2a are located at the same position in the cross-sectional view in the thickness direction of the wiring substrate 200, the shape of the protruding portion 2a is symmetric with respect to the center line of the wiring substrate 200 in the thickness direction. When the center of gravity of the upper surface of the protruding portion 2a and the center of gravity of the lower surface of the protruding portion 2a are located at different positions in the cross-sectional view in the thickness direction of the wiring substrate 200, the shape of the protruding portion 2a is asymmetric with respect to the center line of the wiring substrate 200 in the thickness direction. FIG. 1B illustrates an example in which the shape of the metal member 2 is asymmetric.

As illustrated in FIG. 2, the protruding portion 2a of the metal member 2 has a shape in which a width of the protruding portion 2a continuously increases from the upper surface of the protruding portion 2a toward the lower surface of the protruding portion 2a in the cross-sectional view in the thickness direction of the wiring substrate 200, and other portions 2r₁ and 2r₂ of the upper surface of the metal member 2, other than the upper surface of the protruding portion 2a of the metal member 2, are curved in the cross-sectional view in the thickness direction of the wiring substrate 200. Since the other portions 2r₁ and 2r₂ of the upper surface of the metal member 2, other than the upper surface of the protruding portion 2a of the metal member 2, are curved, the wiring substrate 200 has high thermal conductivity and a high heat dissipation property.

In the cross-sectional view in the thickness direction of the wiring substrate 200, the roundness of the other portions 2r₁ and 2r₂ of the upper surface of the metal member 2, other than the upper surface of the protruding portion 2a of the metal member 2, is not particularly limited, but is preferably a shape corresponding to an arc having a radius in a range from 2 μm to 110 μm. In the cross-sectional view in the thickness direction of the wiring substrate 200, the radius of the roundness of the other portion 2r₁ of the upper surface of the metal member 2 can be the same as or different from the radius of the roundness of the other portion 2r₂ of the upper surface of the metal member 2.

The other portions 2r₁ and 2r₂ of the upper surface of the metal member 2, other than the upper surface of the protruding portion 2a of the metal member 2, can be curved by forming the protruding portion 2a of the metal member 2 by blasting in manufacturing the wiring substrate 200.

The surface roughness Ra of the other portions 2b, 2r₁, and 2r₂ of the upper surface of the metal member 2, other than the upper surface of the protruding portion 2a of the metal member 2, is not particularly limited, but is preferably 350 nm or more, more preferably 500 nm or more. The “other portions 2b, 2r₁, and 2r₂ of the upper surface of the metal member 2” having such a surface roughness Ra are regions of the upper surface of the metal member 2 in contact with the covering member 4. Setting the surface roughness Ra of the other portions 2b, 2r₁, and 2r₂ of the upper surface of the metal member 2 to equal to or greater than 350 nm can be implemented by forming the other portion 2b of the upper surface of the metal member 2 by blasting in manufacturing the wiring substrate 200.

The surface roughness Ra of the upper surface of the protruding portion 2a of the metal member 2 is not particularly limited, but is preferably in a range from 10 nm to 300 nm, more preferably in a range from 30 nm to 200 nm. The “upper surface of the protruding portion 2a of the metal member 2” having such a surface roughness Ra is a region of the upper surface of the metal member 2 that is not in contact with the covering member 4. Setting the surface roughness Ra of the upper surface of the protruding portion 2a of the metal member 2 in a range from 10 nm to 300 nm can be implemented by disposing a protective film on the upper surface of the protruding portion 2a of the metal member 2 so that it is not subjected to blasting in manufacturing the wiring substrate 200.

### Covering Member

The covering member 4 is disposed in contact with the other portions 2b, 2r₁, and 2r₂ of the upper surface of the metal member 2 other than the upper surface of the protruding portion 2a.

The covering member is not particularly limited and can be appropriately selected according to the intended purpose; however, the covering member preferably includes a light reflective member, and can further include other components as necessary. The covering member preferably has a higher reflectance to visible light in the ceramic substrate 100 than in the ceramic plate 1.

Examples of the light reflective member include resin and glass each containing a reflective material.

Examples of the reflective material include titanium oxide, silicon oxide, aluminum oxide, and zinc oxide. Any of these can be used alone or in combination of two or more.

Examples of the resin include thermoplastic resin such as acrylic resin, polycarbonate resin, cyclic polyolefin resin, polyethylene terephthalate resin, polyethylene naphthalate resin, and polyester resin, and thermosetting resin such as epoxy resin and silicone resin. Any of these can be used alone or in combination of two or more.

### Manufacturing Method of Wiring Substrate

The manufacturing method of the wiring substrate according to an embodiment includes preparing a ceramic substrate including a ceramic plate including a first recessed portion disposed in a first surface, a second recessed portion disposed in a second surface opposite to the first surface, and a through hole connecting the first recessed portion and the second recessed portion, and a metal member disposed continuously in the first recessed portion, the second recessed portion, and the through hole; disposing a protective film on a part of at least the metal member of the ceramic substrate; blasting the other part of the metal member other than the part of the metal member provided with the protective film and at least a part of the first surface of the ceramic plate; disposing a covering member in a recessed portion from which the other part of the metal member and at least the part of the first surface of the ceramic plate have been removed by the blasting; and removing the protective film. The manufacturing method of the wiring substrate according to an embodiment preferably further includes polishing or grinding an exposed surface of the covering member after the covering member is disposed, and further includes other steps as necessary.

In the related art, when a complicated wiring pattern or a wiring pattern having a plurality of shapes is to be formed, a formation position of a recessed portion of a ceramic substrate, a size of the recessed portion, and the like can be different, a formation time by laser processing can be different depending on the size of the recessed portion, and a significant time may be required for producing a wiring substrate. In addition, when the recessed portion of the ceramic substrate is small, filling with a conductive member may be insufficient. Moreover, when a light-emitting element is changed or the position of electrodes of the light-emitting element is changed, a different wiring substrate may need to be prepared.

On the other hand, the manufacturing method of the wiring substrate according to an embodiment allows easy formation of various wiring patterns according to the electrode position and shape of an electronic component. That is, by forming the protective film at a position corresponding to the electrode position of the electronic component and blasting a portion other than the portion where the protective film is disposed, a protruding portion can be produced on the metal member. The protruding portion corresponds to the electrode position of the electronic component. Even when electrodes of the electronic component are small, the protruding portion can be easily manufactured. In addition, the position of the protruding portion can be changed without changing the ceramic substrate. Moreover, a protruding portion including a part of the metal member and a part of the ceramic plate can be formed, so that mounting of the electronic component can be simplified. In addition, small light-emitting elements or different types of light-emitting elements can be used on the surface.

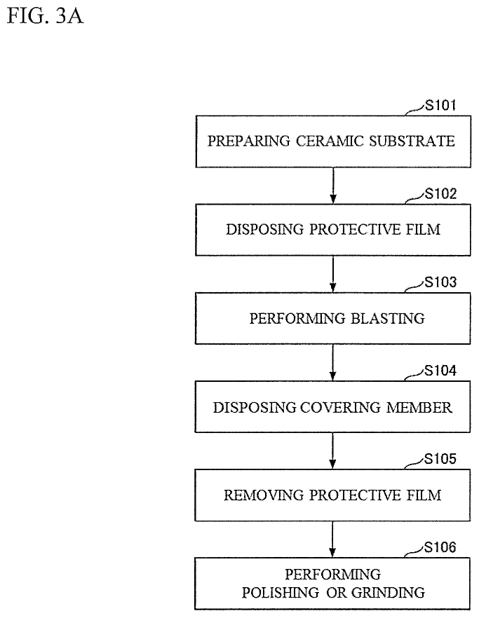

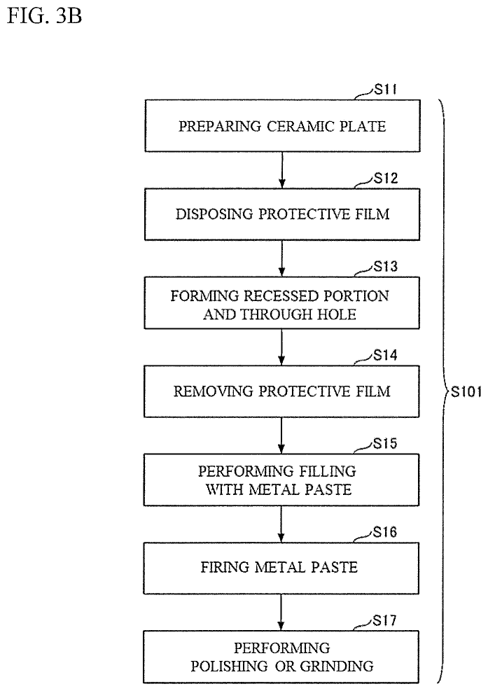

FIG. 3A is a flowchart showing an example of the manufacturing method of the wiring substrate according to an embodiment. FIG. 3B is a flowchart showing an example of the preparing of the ceramic substrate in the manufacturing method of the wiring substrate according to an embodiment.

As shown in FIG. 3A, the manufacturing method of the wiring substrate according to an embodiment includes S101 of preparing the ceramic substrate, S102 of disposing the protective film, S103 of performing blasting, S104 of disposing the covering member, and S105 of removing the protective film, and can further include S106 of performing polishing or grinding.

As shown in FIG. 3B, S101 of preparing the ceramic substrate preferably includes S11 of preparing the ceramic plate, S12 of disposing the protective film, S13 of forming a recessed portion and a through hole, S14 of removing the protective film, S15 of performing filling with a metal paste, S16 of firing the metal paste, and S17 of performing polishing or grinding.

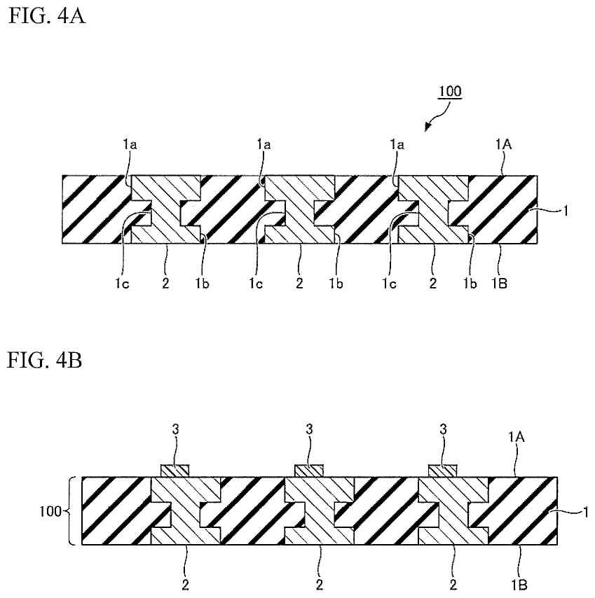

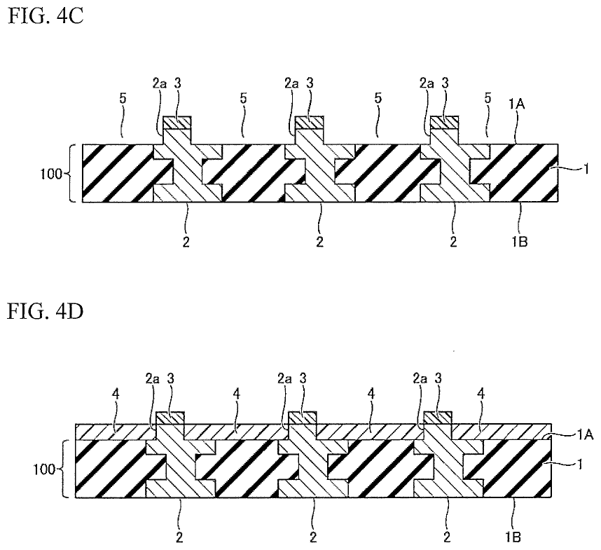

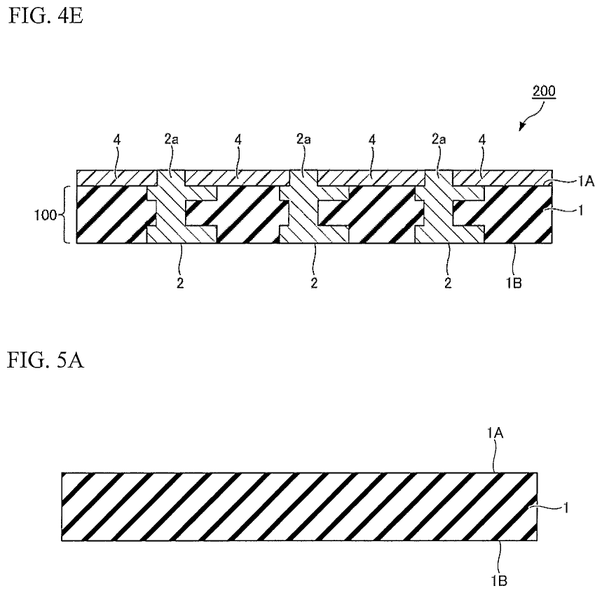

FIG. 4A is a schematic cross-sectional view illustrating the preparing of the ceramic substrate. FIG. 4B is a schematic cross-sectional view illustrating the disposing of the protective film. FIG. 4C is a schematic cross-sectional view illustrating performing the blasting. FIG. 4D is a schematic cross-sectional view illustrating the disposing of the covering member. FIG. 4E is a schematic cross-sectional view illustrating the removing of the protective film.

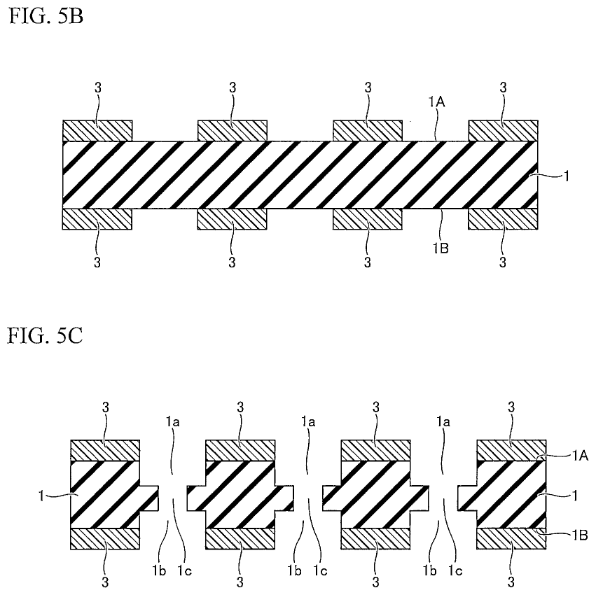

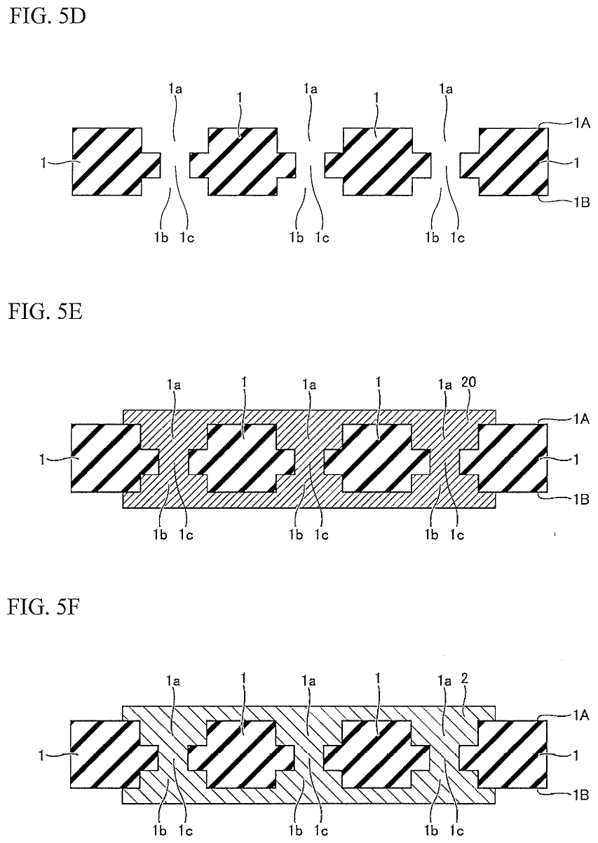

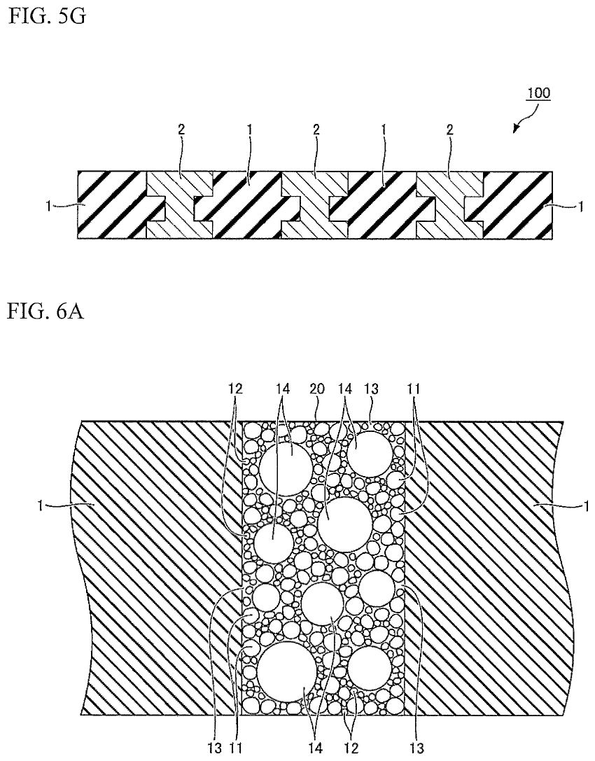

FIG. 5A is a schematic cross-sectional view illustrating the preparing of the ceramic plate in the preparing of the ceramic substrate. FIG. 5B is a schematic cross-sectional view illustrating the disposing of the protective film in the preparing of the ceramic substrate. FIG. 5C is a schematic cross-sectional view illustrating the forming of the through hole in the preparing of the ceramic substrate. FIG. 5D is a schematic cross-sectional view illustrating the removing of the protective film in the preparing of the ceramic substrate. FIG. 5E is a schematic cross-sectional view illustrating the performing filling with the metal paste in the preparing of the ceramic substrate. FIG. 5F is a schematic cross-sectional view illustrating the firing of the metal paste in the preparing of the ceramic substrate. FIG. 5G is a schematic cross-sectional view illustrating performing the polishing or grinding in the preparing of the ceramic substrate.

### S101: Preparing Ceramic Substrate

As illustrated in FIG. 4A, in S101 of preparing the ceramic substrate, the ceramic substrate 100 is prepared which includes the ceramic plate 1 having the first recessed portion 1a disposed in the first surface 1A, the second recessed portion 1b disposed in the second surface 1B opposite to the first surface 1A, and the through hole 1c connecting the first recessed portion 1a and the second recessed portion 1b, and the metal member 2 disposed continuously in the first recessed portion 1a, the second recessed portion 1b, and the through hole 1c.

### S11: Preparing Ceramic Plate

In S11 of preparing the ceramic plate, the ceramic plate 1 having a flat plate shape is preferably prepared as illustrated in FIG. 5A.

The ceramic plate 1 can be a ceramic precursor before sintering or can be a sintered ceramic; however, a sintered ceramic is preferable because the sintered ceramic has no dimensional change due to firing. In addition, when a ceramic precursor before sintering is used as the ceramic plate 1, the ceramic plate 1 is preferably sintered for use before S12 of disposing the protective film.

The thickness of the ceramic plate 1 having a flat plate shape is not particularly limited, but is preferably in a range from 50 μm to 500 μm, more preferably in a range from 80 μm to 400 μm.

### S12: Disposing Protective Film

In S12 of disposing the protective film, as illustrated in FIG. 5B, a protective film 3 is disposed on each of the first surface 1A and the second surface 1B of the ceramic plate 1.

The position and size of the protective film 3 are not particularly limited, and the protective film 3 can be disposed on a part of each of the first surface 1A and the second surface 1B of the ceramic plate 1 or can be disposed on the entire surface thereof. However, a protective film having a desired shape pattern is preferably disposed on the entire surface of each of the first surface 1A and the second surface 1B.

The shape of the protective film 3 is not particularly limited and can be appropriately selected according to the arrangement and the like of the electrodes of the light-emitting element, the electrodes of the mounting substrate. Specifically, the protective film 3 is preferably disposed in a region not corresponding to the electrodes of the light-emitting element and the electrodes of the mounting substrate.

The type of the protective film 3 is not particularly limited, and examples thereof include a resist and a dry film. The resist can be either positive or negative.

When a resist is used as the protective film 3, the resist is exposed and developed in S13 of forming a recessed portion and a through hole to form a protective film that covers the region of the first surface 1A of the ceramic plate 1 other than the first recessed portion 1a on the first surface 1A of the ceramic plate 1 and the second surface 1B of the ceramic plate 1 other than the second recessed portion 1b on the second surface 1B of the ceramic plate 1.

### S13: Forming Recessed Portion and Through Hole

In S13 of forming a recessed portion and a through hole, as illustrated in FIG. 5C, the first recessed portion 1a is formed in the first surface 1A of the ceramic plate 1, the second recessed portion 1b is formed in the second surface 1B opposite to the first surface 1A, and the through hole 1c connecting the first recessed portion 1a and the second recessed portion 1b is formed. The first recessed portion 1a, the second recessed portion 1b, and the through hole 1c are formed in a region of the ceramic plate 1 where the protective film 3 is not disposed, in S12 of disposing the protective film.

A method of forming the first recessed portion 1a, the second recessed portion 1b, and the through hole 1c is not particularly limited and can be appropriately selected according to the type of the protective film 3, and examples thereof include a method of etching the ceramic plate 1, a method of blasting the ceramic plate 1, and a method of performing laser processing on the ceramic plate 1. The etching method can be wet etching or dry etching. Any of these methods can be performed alone or in combination of two or more.

### S14: Removing Protective Film

In S14 of removing the protective film, as illustrated in FIG. 5D, the protective film 3 is removed from the ceramic plate 1 in which the first recessed portion 1a is formed in the first surface 1A of the ceramic plate 1, the second recessed portion 1b is formed in the second surface 1B opposite to the first surface 1A, and the through hole 1c connecting the first recessed portion 1a and the second recessed portion 1b is formed in S13 of forming a recessed portion and a through hole.

A method of removing the protective film 3 is not particularly limited and can be appropriately selected according to the type of the protective film 3, and the protective film 3 can be removed by peeling or can be removed by polishing or grinding.

S15: Performing Filling with Metal Paste

In S15 of performing filling with the metal paste, as illustrated in FIG. 5E, the first recessed portion 1a, the second recessed portion 1b, and the through hole 1c of the ceramic plate 1 are filled with a metal paste 20.

In S15 of performing filling with the metal paste, the metal paste 20 preferably covers not only the first recessed portion 1a, the second recessed portion 1b, and the through hole 1c of the ceramic plate 1 but also at least a part of the first surface 1A and the second surface 1B of the ceramic plate 1. Thus, even though the volume of the metal paste 20 is reduced when the metal paste 20 is fired in S16 of firing the metal paste, the thickness of the metal member 2 can be made sufficiently thick.

### Metal Paste 20

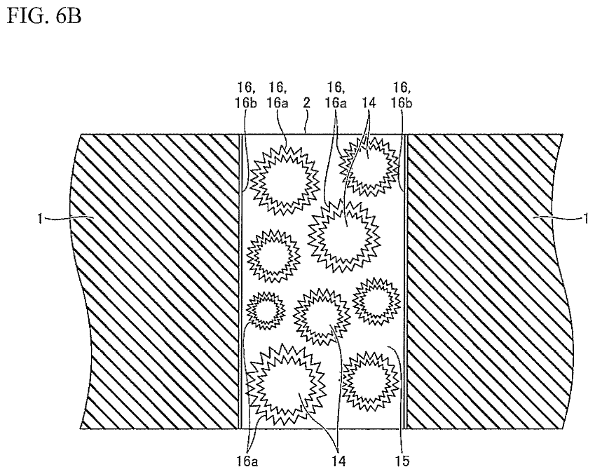

FIG. 6A is an enlarged cross-sectional view schematically illustrating a state of the ceramic plate on which the metal paste is disposed in the preparing of the ceramic substrate. FIG. 6B is an enlarged cross-sectional view schematically illustrating a state of the metal member after the ceramic plate provided with the metal paste in FIG. 6A is sintered.

The metal paste 20 is not particularly limited, but preferably includes metal powder 11 and active metal powder 12 from the viewpoint of improving adhesion to the ceramic plate 1, and further includes other components as necessary.

### Metal Powder

The metal powder 11 is not particularly limited, and examples thereof include silver, copper, a silver-copper eutectic alloy, a copper-zinc eutectic alloy, and a copper-tin eutectic alloy. Any of these can be used alone or in combination of two or more. Among the materials, the silver-copper eutectic alloy is preferable.

The melting point of the metal powder 11 is not particularly limited, but is preferably in a range from 700° C. to 1200° C., more preferably in a range from 700° C. to 1100° C., even more preferably in a range from 750° C. to 900° C.

### Active Metal Powder

The active metal powder 12 is not particularly limited, and examples thereof include TiH₂, CeH₂, ZrH₂, and MgH₂. Any of these can be used alone or in combination of two or more.

### Other Components

The other components in the metal paste 20 are not particularly limited, and examples thereof include an organic binder 13, an inorganic filler 14, and a reducing agent such as an organic acid. Any of these can be used alone or in combination of two or more.

The organic binder 13 is not particularly limited, and examples thereof include a thermosetting resin and a thermoplastic resin. Specific examples of the organic binder 13 include epoxy resins, silicone resins, acrylic resins, urethane resins, polyvinyl resins, ethyl cellulose resins, phenol resins, polyimide resins, polyurethane resins, melamine resins, and polyurea resins. As the organic binder 13, a solvent and a resin material generally used as a via material can be used. Any of these can be used alone or in combination of two or more. Since the organic binder 13 functions as a sintering binder, the organic binder 13 is decomposed, evaporated, and removed in S16 of firing the metal paste.

The inorganic filler 14 is not particularly limited, and examples thereof include a ceramic filler, a metal filler, and a glass filler. Any of these can be used alone or in combination of two or more. Among the materials, the ceramic filler is preferable as the inorganic filler 14. When the metal paste 20 includes the inorganic filler 14, the thermal conductivity and the heat dissipation property of the metal member 2 can be improved.

The ceramic filler is not particularly limited, and examples thereof include aluminum nitride (AlN), silicon nitride (Si₃N₄), aluminum oxide (Al₂O₃), and silicon carbide (SiC).

In addition, the inorganic filler 14 is preferably a material having a linear expansion coefficient of 8 ppm or less. Thus, the linear coefficient of the metal member 2 can be lowered and thermal shock characteristics can be improved.

The median diameter of the inorganic filler 14 is not particularly limited, but is preferably in a range from 1 μm to 50 μm, more preferably in a range from 2 μm to 15 μm.

The inorganic filler 14 is preferably a material having a linear expansion coefficient of 5 ppm or less and a high thermal conductivity of 100 W/m·K or more. Examples of such a material include the ceramic filler. By dispersing and disposing such a material in the metal member 2, the difference in linear expansion coefficient can be reduced and reliability such as thermal shock characteristics can be improved.

The thermal conductivity of the inorganic filler 14 is not particularly limited, but is preferably 20 W/(m/K) or more, more preferably 30 W/(m/K) or more at a measurement temperature of 300 K.

In the metal paste 20, when the total content of the metal powder 11, the active metal powder 12, and the inorganic filler 14 is set to 100 mass %, the content of the metal powder 11 is preferably in a range from 40 mass % to 99 mass %, the content of the active metal powder 12 is preferably in a range from 0.5 mass % to 15 mass %, and the content of the inorganic filler 14 is preferably in a range from 1 mass % to 50 mass %.

### S16: Firing Metal Paste

In S16 of firing the metal paste, as illustrated in FIG. 5F, the metal paste 20 filling the first recessed portion 1a, the second recessed portion 1b, and the through hole 1c of the ceramic plate 1 in S15 of performing filling with the metal paste is fired to form the metal member 2. When the metal paste 20 is disposed covering at least a part of the first surface 1A and the second surface 1B of the ceramic plate 1 in S15 of performing filling with the metal paste, the metal paste 20 is fired in the same manner to form the metal member 2.

In S16 of firing the metal paste, the metal paste 20 is preferably dried after S15 of performing filling with the metal paste and before the metal paste 20 is fired. The drying temperature is not particularly limited and an example thereof includes a temperature lower than the firing temperature of the metal paste 20.

The firing temperature when the metal paste 20 is fired is not particularly limited, but is preferably in a range from 700° C. to 1100° C., more preferably in a range from 720° C. to 1000° C., even more preferably in a range from 750° C. to 900° C.

The firing time when the metal paste 20 is fired is not particularly limited, but is preferably in a range from 5 minutes to 90 minutes, more preferably in a range from 10 minutes to 60 minutes, even more preferably in a range from 15 minutes to 30 minutes.

As illustrated in FIG. 6B, the metal member 2 produced using the metal paste 20 includes, for example, a metal 15, a metal compound 16, and the inorganic filler 14. The organic binder 13 is evaporated and removed by firing the metal paste 20.

In the metal member 2, for example, when the total content of the metal 15, the metal compound 16, and the inorganic filler 14 is set to 100 mass %, the content of the metal 15 is preferably in a range from 40 mass % to 95 mass %, the content of the metal compound 16 is preferably in a range from 1 mass % to 10 mass %, and the content of the inorganic filler 14 is preferably in a range from 5 mass % to 50 mass %. When the metal member 2 includes the inorganic filler 14 at a predetermined ratio, volume shrinkage can be reduced. In addition, since the metal member 2 includes the metal 15 at a predetermined ratio, the inorganic filler 14 can be dispersed in the metal 15 that is continuous.

In the metal member 2, the metal 15 is a metal member serving as a core of the metal member 2 together with the inorganic filler 14. The metal 15 is disposed in a state in which the inorganic filler 14 is dispersed.

In S16 of firing the metal paste, the metal powder 11 in the metal paste 20 is fired to become the metal 15. Consequently, the kind of metal of the metal 15 is specified by the kind of metal of the metal powder 11, and examples thereof include silver, copper, a silver-copper eutectic alloy, a copper-zinc eutectic alloy, and a copper-tin eutectic alloy. Among the materials, the silver-copper eutectic alloy is preferable.

The inorganic filler 14 is disposed in the metal member 2 in a state in which a plurality of particles thereof are dispersed. A plurality of inorganic fillers 14 indicate that the inorganic filler 14 is not one particle but a plurality of particles.

The inorganic filler 14 is preferably disposed in a range from 10 μm² to 75 μm² per 100 μm² in a cross-sectional view in the thickness direction of the ceramic substrate 100 of the metal member 2.

The metal compound 16 is formed by firing the active metal powder 12. By firing the metal paste 20, a reaction layer of the inorganic filler 14 and the active metal powder 12 is formed on the surface of the inorganic filler 14. The metal compound 16 is mainly disposed on at least a part or all of the surface of the inorganic filler 14 and at least a part of inner walls of the first recessed portion 1a, the second recessed portion 1b, and the through hole 1c in the ceramic plate 1. The metal compound 16 includes a filler-surface metal compound 16a disposed on the surface of the inorganic filler 14 and a wall-surface metal compound 16b disposed on at least a part of the inner walls of the first recessed portion 1a, the second recessed portion 1b, and the through hole 1c in the ceramic plate 1. Preferably, the active metal powder 12, the inorganic filler 14, and components of the inner walls of the first recessed portion 1a, the second recessed portion 1b, and the through hole 1c in the ceramic plate 1 are fired, so that the filler-surface metal compound 16a and the wall-surface metal compound 16b are disposed as reaction products.

The filler-surface metal compound 16a is the metal compound 16 and covers at least a part or all of the surface of the inorganic filler 14. For example, when the inorganic filler 14 is AlN or Si₃N₄, the filler-surface metal compound 16a is formed on the surface of the inorganic filler 14 as TiN by a reaction between the inorganic filler 14 and TiH₂ of the active metal powder 12 before firing, for example. The surface of the filler-surface metal compound 16a is provided with continuous jagged irregularities, and the surface of the inorganic filler 14 is also provided with jagged irregularities. The inorganic fillers 14 each having a surface provided with the filler-surface metal compound 16a are dispersed in the metal member 2 that is continuous.

The wall-surface metal compound 16b is disposed as the metal compound 16 on at least a part of the inner walls of the first recessed portion 1a, the second recessed portion 1b, and the through hole 1c in the ceramic plate 1. For example, in a case in which the ceramic plate 1 is at least one selected from silicon nitride, aluminum nitride, and boron nitride and the active metal powder 12 before firing is, for example, TiH₂ and TiN, a reaction product is generated and the wall-surface metal compound 16b is formed as a compound on the inner walls of the first recessed portion 1a, the second recessed portion 1b, and the through hole 1c in the ceramic plate 1. The wall-surface metal compound 16b is in a state of having jagged irregularities continuously formed on the inner walls of the first recessed portion 1a, the second recessed portion 1b, and the through hole 1c in the ceramic plate 1, so that the connection strength between the metal member 2 and each of the inner walls of the first recessed portion 1a, the second recessed portion 1b, and the through hole 1c in the ceramic plate 1 is improved.

### S17: Performing Polishing or Grinding

In S17 of performing the polishing or grinding, as illustrated in FIG. 5G, the surface of the metal member 2 exposed on the first surface 1A and the second surface 1B of the ceramic plate 1 of the ceramic substrate 100 obtained in S16 of firing the metal paste and the surfaces of the ceramic plate 1 exposed on the first surface 1A and the second surface 1B of the ceramic plate 1 are polished or ground.

The ceramic substrate 100 obtained in S16 of firing the metal paste can be used as is in S102 of disposing the protective film, for example, when only the first recessed portion 1a, the second recessed portion 1b, and the through hole 1c of the ceramic plate 1 are filled with the metal paste 20 in S15 of performing filling with the metal paste; however, for example, when the metal paste 20 is disposed covering at least a part of the first surface 1A and the second surface 1B of the ceramic plate 1, S17 of performing the polishing or grinding is further performed so that the first surface 1A and the second surface 1B of the ceramic plate 1 and the surface (exposed surface) of the metal member 2 can be made substantially flush with each other.

In S16 of firing the metal paste, the first surface 1A and the second surface 1B of the ceramic plate 1 can be blackened, but the blackening can be removed by polishing or grinding.

### S102: Disposing Protective Film

In S102 of disposing the protective film, the protective film 3 is disposed on a part of at least the metal member 2 of the ceramic substrate 100 as illustrated in FIG. 4B.

In S102 of disposing the protective film, the protective film 3 can be disposed on a part of the first surface 1A of the ceramic plate 1 in the ceramic substrate 100, or can be continuously disposed on a part of the metal member 2 of the ceramic substrate 100 and a part of the first surface 1A of the ceramic plate 1.

In S102 of disposing the protective film, the protective film 3 can be disposed on at least the first surface 1A side of the ceramic plate 1, but can be disposed on the second surface 1B side of the ceramic plate 1.

The arrangement of the protective film 3 is not particularly limited, and the protective film 3 can be disposed on a part of each of the first surface 1A and the second surface 1B of the ceramic plate 1 in the ceramic substrate 100 or can be disposed on the entire surface thereof; however, the protective film having a desired shape pattern is preferably disposed on the entire surface of each of the first surface 1A and the second surface 1B.

The type of the protective film 3 is not particularly limited, and examples thereof include a resist and a dry film. The resist can be either positive or negative.

The plan view shape of the protective film 3 is not particularly limited and can be appropriately selected according to the arrangement and the like of the electrodes on the mounting substrate side, and examples thereof include polygons such as a triangle, a quadrangle, a pentagon, and a hexagon, a circle, and an ellipse. The shape can be a combination of these shapes. Specifically, the protective film 3 is preferably disposed in a region not corresponding to the electrodes on the mounting substrate side.

The shape of the protective film 3 disposed on the first surface 1A of the ceramic plate 1 in the ceramic substrate 100 can be the same as or different from the shape of the protective film 3 disposed on the second surface 1B of the ceramic plate 1 in the ceramic substrate 100. The shape of the protective film 3 disposed on the first surface 1A and the shape of the protective film 3 disposed on the second surface 1B can be appropriately selected in accordance with the structure, shape, dimensions, and the like of the light-emitting element.

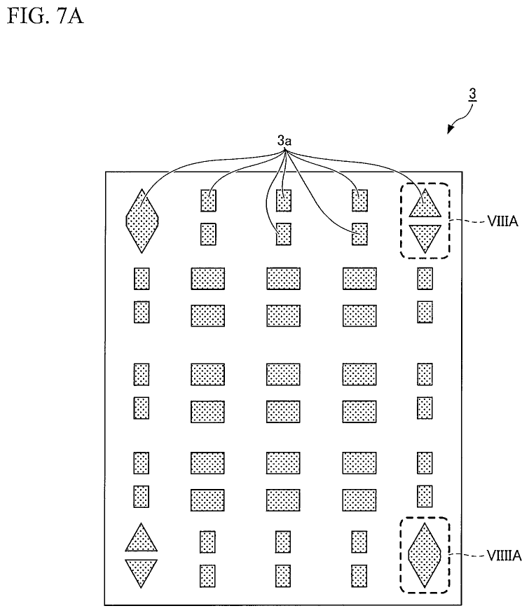

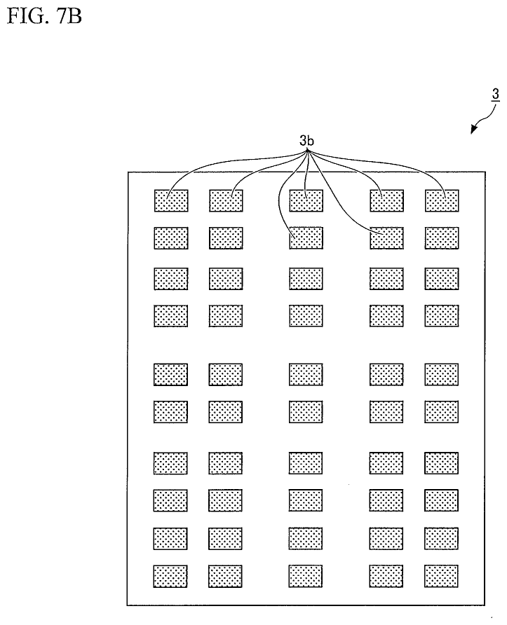

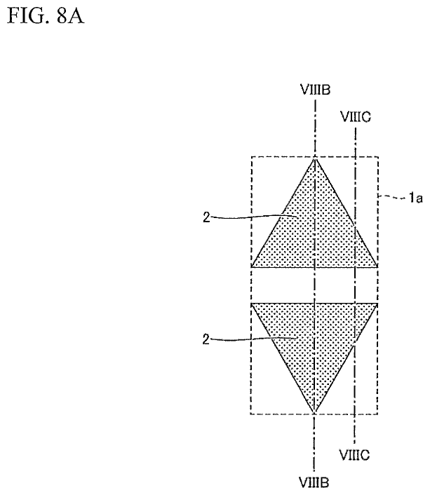

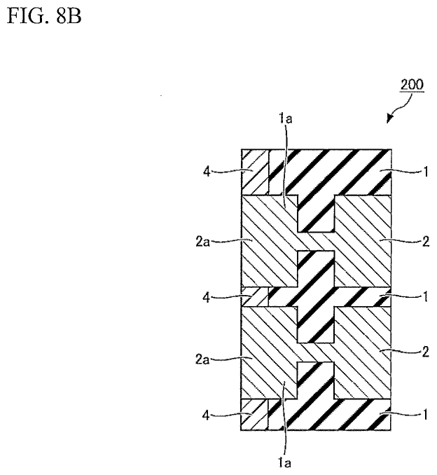

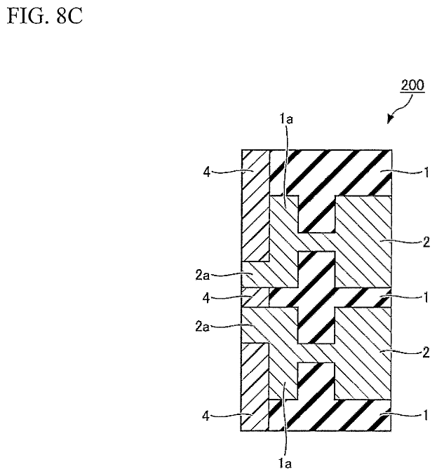

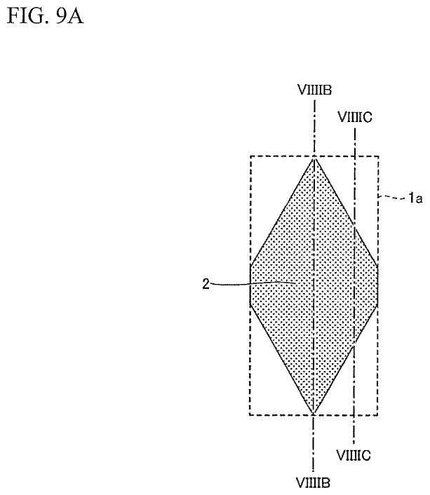

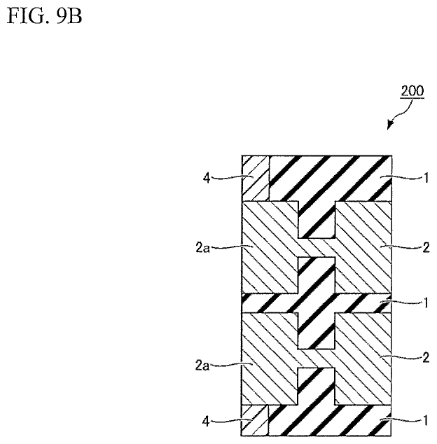

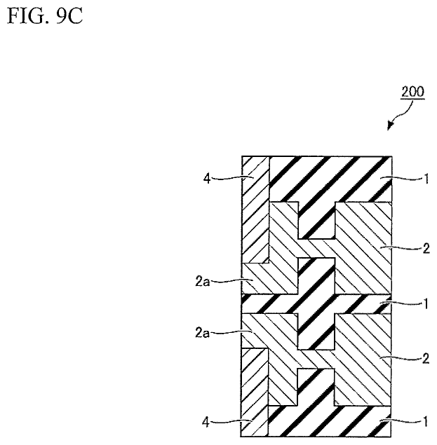

Specific examples of the protective film 3 are illustrated in FIGS. 7A, 7B, 8A to 8C, and 9A to 9C. FIG. 7A is a schematic plan view illustrating an example of a shape pattern of a protective portion in a protective film used on the first surface of the ceramic substrate in the disposing of the protective film. FIG. 7B is a schematic plan view illustrating an example of a shape pattern of a protective portion in a protective film used on the second surface of the ceramic substrate in the disposing of the protective film. FIG. 8A is a schematic enlarged view of a metal member in plan view of a wiring substrate produced using a region VIIIA of the protective film illustrated in FIG. 7A. FIG. 8B is a schematic cross-sectional view of the wiring substrate taken along line VIIIB-VIIIB in FIG. 8A. FIG. 8C is a schematic cross-sectional view of the wiring substrate taken along line VIIIC-VIIIC in FIG. 8A. FIG. 9A is a schematic enlarged view of a metal member in plan view of the wiring substrate produced using a region VIIIIA of the protective film illustrated in FIG. 7A. FIG. 9B is a schematic cross-sectional view of the wiring substrate taken along line VIIIIB-VIIIIB in FIG. 9A. FIG. 9C is a schematic cross-sectional view of the wiring substrate taken along line VIIIIC-VIIIIC in FIG. 9A. In FIGS. 7B, 7C, 8B, and 8C, the first surface of the wiring substrate 200 is illustrated on the left side of the drawings and the second surface of the wiring substrate 200 is illustrated on the right side of the drawings.

In FIGS. 7A and 7B, a colored portion is the protective film 3. A portion protected by the protective film 3 becomes the protruding portion 2a after S103 of performing the blasting. Since the protruding portion 2a includes the metal member 2, the protruding portion 2a can correspond to the positions of electrodes of electronic components having various wiring patterns. Accordingly, since the manufacturing method of the wiring substrate according to an embodiment includes S103 of performing the blasting, wirings corresponding to the positions of the electrodes of the electronic components can be easily manufactured even in the case of wiring patterns having a plurality of shapes, complicated shapes, and small dimensions as illustrated in FIG. 7A.

When the protective film 3 illustrated in FIG. 7A is used, the metal member 2 covered with the region VIIIA in FIG. 7A becomes the protruding portion 2a exposed on the first surface 1A of the ceramic plate 1 in the wiring substrate 200 after the blasting. In this case, the protruding portion 2a has a triangular shape indicated by a solid line in FIG. 8A. In FIG. 8A, a dotted line is a virtual line indicating the shape of the bottom portion of the first recessed portion 1a of the ceramic plate 1. As illustrated in FIGS. 8A to 8C, the shape of the metal member 2 in the first recessed portion 1a of the ceramic plate 1 is different from the shape of the upper surface of the protruding portion 2a exposed on the first surface 1A.

As another example, when the protective film 3 illustrated in FIG. 7A is used, the metal member 2 covered with the region VIIIIA in FIG. 7A becomes the protruding portion 2a exposed on the first surface 1A of the ceramic plate 1 in the wiring substrate 200 after the blasting. In this case, the protruding portion 2a has a shape indicated by a solid line in FIG. 9A. In FIG. 9A, a dotted line is a virtual line indicating the shape of the bottom portion of the first recessed portion 1a of the ceramic plate 1. As illustrated in FIGS. 9A to 9C, the shape of the metal member 2 in the first recessed portion 1a of the ceramic plate 1 is different from the shape of the upper surface of the protruding portion 2a exposed on the first surface 1A. In FIG. 9B, unlike in the case of FIG. 8B, the covering member 4 is not disposed between the one metal member 2 and the other metal member 2 on the surface provided with the covering member 4.

### S103: Performing Blasting

In S103 of performing the blasting, as illustrated in FIG. 4C, the other part of the metal member 2 other than a part of the metal member 2 on which the protective film 3 is disposed and at least a part of the first surface 1A of the ceramic plate 1 are blasted. Thus, a recessed portion 5, from which the other part of the metal member 2 and at least a part of the first surface 1A of the ceramic plate 1 have been removed, is formed. In other words, with respect to the other part of the metal member 2 other than the part of the metal member 2 on which the protective film 3 is disposed and the first surface 1A of the ceramic plate 1, the part of the metal member 2 on which the protective film 3 is disposed, and further, as necessary, at least a part of the first surface 1A of the ceramic plate 1 become the protruding portion 2a.

In S103 of performing the blasting, at least the first surface 1A side of the ceramic plate 1 can be blasted, but the second surface 1B side of the ceramic plate 1 can also be blasted. In the case in which the protective film 3 is disposed on the second surface 1B side of the ceramic plate 1 in S102 of disposing the protective film, the second surface 1B side of the ceramic plate 1 is also suitably blasted in S103 of performing the blasting. Thus, a recessed portion, from which the other part of the metal member 2 and a part of the second surface 1B of the ceramic plate 1 have been removed, is formed.

The second surface 1B of the ceramic plate 1 can be processed by another method such as etching or laser processing to form the recessed portion.

The blasting can be wet blasting or dry blasting. Of these, the dry blasting is preferable in that a predetermined shape can be formed regardless of the type of a solution.

By the blasting, the protruding portion 2a has the structure illustrated in FIG. 2 as described in the item of [wiring substrate]. Thus, the surface area of the metal member 2 in the wiring substrate 200 is increased, so that the thermal conductivity and the heat dissipation property are improved. In addition, the conductivity of the wiring substrate 200 in the plan view direction is improved.

In addition, by the blasting, the center of gravity of the upper surface of the protruding portion 2a of the metal member 2 and the center of gravity of the lower surface of the protruding portion 2a can be located at different positions. In this way, in the cross-sectional view in the thickness direction of the wiring substrate 200, the shape of the metal member 2 can be made asymmetric, and a wiring pattern can be freely designed.

The surfaces of the other portion 2b of the upper surface of the metal member 2 other than the upper surface of the protruding portion 2a of the metal member 2 on which the protective film 3 is not disposed and which is subjected to the blasting and at least a part of the first surface 1A of the ceramic plate 1 are rougher than the surface of the part of the metal member 2 on which the protective film 3 is disposed. The surface roughness Ra of the other portion 2b of the upper surface of the metal member 2 other than the upper surface of the protruding portion 2a of the metal member 2 on which the protective film 3 is disposed and at least a part of the first surface 1A of the ceramic plate 1 is as described in the item of [wiring substrate].

In addition, the surface roughness Ra of the upper surface of the protruding portion 2a of the metal member 2 on which the protective film 3 is disposed and the other part other than at least a part of the first surface 1A of the ceramic plate 1 is also as described in the item of [wiring substrate].

When the second surface 1B of the ceramic plate 1 is subjected to blasting in the same manner as the first surface 1A of the ceramic plate 1, at least a part of the metal member 2 and at least a part of the second surface of the ceramic plate on which the protective film is disposed, and the other part other than at least a part of the metal member 2 and the other part other than at least a part of the second surface of the ceramic plate on which the protective film is not disposed also include protruding portions formed in the same manner and have the same surface roughness Ra as those in the case in which the first surface 1A of the ceramic plate 1 is subjected to blasting.

### S104: Disposing Covering Member

In S104 of disposing the covering member, as illustrated in FIG. 4D, the covering member 4 is disposed in the recessed portion 5 from which the other portion 2b of the upper surface of the metal member 2 other than the protruding portion 2a and at least a part of the first surface 1A of the ceramic plate 1 have been removed by the blasting.

In S104 of disposing the covering member, in another mode, the covering member 4 can be disposed covering the protective film 3.

### S105: Removing Protective Film

In S105 of removing the protective film, as illustrated in FIG. 4E, the protective film 3 disposed in S102 of disposing the protective film is removed.

A method of removing the protective film 3 is not particularly limited and can be appropriately selected according to the type of the protective film 3. The protective film 3 can be removed by peeling or can be removed in S106 of performing the polishing or grinding.

### S106: Performing Polishing or Grinding

In S106 of performing the polishing or grinding, the first surface 1A of the ceramic plate 1 is polished or ground after the covering member is disposed. The final wiring substrate 200 can be obtained without performing S106 of performing the polishing or grinding; however, by performing polishing or grinding, the exposed surface of the covering member 4 can be flattened, and light-emitting elements can be disposed on the wiring substrate 200 without wobbling. In addition, when the light-emitting elements are disposed on the wiring substrate 200, light from the light-emitting elements can be efficiently reflected by the covering member 4, and can be reflected in upward and obliquely upward directions.

### EXAMPLES

The present invention is specifically described below with reference to an example, but the embodiments are not limited to the example at all.

### First Example

The ceramic substrate 100 having a thickness of 330 μm illustrated in FIG. 4A was prepared. The ceramic substrate 100 was produced by filling the first recessed portion 1a, the second recessed portion 1b, and the through hole 1c of the ceramic plate 1 with the metal paste 20, firing the ceramic plate 1 at 850° C., and polishing the fired ceramic plate 1 by the method illustrated in FIGS. 5A to 5G on the basis of the flowchart shown in FIG. 3B. The metal paste 20 was prepared by mixing 89 mass % of a silver-copper eutectic alloy as the metal powder 11, 5 mass % of TiH₂ as the active metal powder 12, 1 mass % of a polyvinyl ester resin as the organic binder 13, and 5 mass % of AlN as the inorganic filler 14.

By using the produced ceramic substrate 100, the wiring substrate 200 was produced by the method described in FIGS. 4A to 4E on the basis of the flowchart shown in FIG. 3A. Specifically, on the first surface 1A of the ceramic plate 1 in the produced ceramic substrate 100, a dry film having the shape pattern illustrated in FIG. 7A was disposed, and dry blasting was performed. Subsequently, the covering member 4 was formed on the dry film by using a covering member material containing 45 mass % of titanium oxide and 55 mass % of epoxy resin. Subsequently, the covering member 4 was polished and the dry film was removed to obtain the wiring substrate 200.

### Evaluation of Shape of Protruding Portion 2a

A cross section in the thickness direction of the wiring substrate 200 of the first example was prepared using a focused ion beam scanning electron microscope (FIB-SEM) “Heloes450s” manufactured by FEI Company, and the shape of the protruding portion 2a of the metal member 2 was observed to be the shape illustrated in FIG. 2.

### Evaluation of Surface Roughness Ra

In the wiring substrate 200 of the first example, the surface roughness Ra of each of the upper surface of the protruding portion 2a of the metal member 2 on which the dry film was disposed and the other portion 2b of the upper surface of the metal member 2 other than the upper surface of the protruding portion 2a of the metal member 2 on which the dry film was not disposed was measured in accordance with JIS B 0601:2013 by using a stylus type surface roughness measuring instrument (Surfcorder SE 3500 manufactured by Kosaka Laboratory Ltd.) including a diamond stylus with a tip radius r of curvature of 2 μm.

As a result, the surface roughness Ra of the upper surface of the protruding portion 2a of the metal member 2 on which the dry film was disposed was 120 nm, and the surface roughness Ra of the other portion 2b of the upper surface of the metal member 2 other than the upper surface of the protruding portion 2a of the metal member 2 on which the dry film was not disposed was 424 nm.

### Evaluation of Adhesion

In the wiring substrate 200 of the first example, the adhesion of the covering member 4 to each of the upper surface of the protruding portion 2a of the metal member 2 on which the dry film was disposed and the other portion 2b of the upper surface of the metal member 2 other than the upper surface of the protruding portion 2a of the metal member 2 on which the dry film was not disposed was evaluated by a shear test using a bond tester manufactured by DAGE Products Co., Ltd.

As a result, the adhesion of the covering member 4 to the other portion 2b of the upper surface of the metal member 2 other than the upper surface of the protruding portion 2a of the metal member 2 on which the dry film was not disposed was higher than the adhesion of the covering member 4 to the upper surface of the protruding portion 2a of the metal member 2 on which the dry film was disposed.

As described above, the present invention has been described on the basis of specific embodiments, but these are merely presented as examples, and the present invention is not limited to the above embodiments. The above embodiments can be embodied in various other forms, and various combinations, omissions, substitutions, additions, modifications, and the like can be made without departing from the spirit of the invention. These embodiments and variations thereof are included in the scope and spirit of the invention and are within the scope of the invention described in the claims and equivalents thereof.

1. A method of manufacturing a wiring substrate, the method comprising:
preparing a ceramic substrate comprising a ceramic plate having a first recessed portion disposed in a first surface of the ceramic plate, a second recessed portion disposed in a second surface of the ceramic plate opposite to the first surface, and a through hole connecting the first recessed portion and the second recessed portion, the ceramic substrate further comprising a metal member disposed continuously in the first recessed portion, the second recessed portion, and the through hole;
disposing a protective film on a part of at least the metal member of the ceramic substrate;
blasting an other part of the metal member other than the part of the metal member provided with the protective film and at least a part of the first surface of the ceramic plate;
disposing a covering member in a recessed portion from which the other part of the metal member and the at least a part of the first surface of the ceramic plate have been removed by the blasting; and
removing the protective film.

2. The method according to claim 1, wherein, in the preparing of the ceramic substrate, the ceramic plate is a sintered ceramic plate.

3. The method according to claim 1, wherein, in the disposing of the protective film, the protective film is continuously disposed on the part of at least the metal member and the part of the first surface of the ceramic plate.

4. The method according to claim 1, wherein, in the disposing of the protective film, a shape of the protective film in plan view is a polygonal shape, a circular shape, an elliptical shape, or a combination of any of these shapes.

5. The method according to claim 1, wherein, in the disposing of the covering member, the covering member comprises a light reflective member.

6. The method according to claim 1, wherein, in the disposing of the covering member, the covering member is disposed covering the protective film.

7. The method according to claim 6, further comprising:
polishing or grinding an exposed surface of the covering member after the disposing of the covering member.

8. The method according to claim 1, wherein, in the preparing of the ceramic substrate, the first recessed portion, the second recessed portion, and the through hole are filled with a metal paste and the metal paste is fired to form the metal member.

9. The method according to claim 8, wherein, in the preparing of the ceramic substrate, a temperature of the firing is in a range from 700° C. to 1100° C.

10. The method according to claim 1, wherein, in the preparing of the ceramic substrate, a maximum diameter of the metal member disposed in the first recessed portion when viewed in plan view is greater than a maximum diameter of the metal member disposed in the through hole when viewed in plan view.

11. A wiring substrate comprising:
a ceramic substrate comprising a ceramic plate having a first recessed portion disposed in a first surface of the ceramic plate, a second recessed portion disposed in a second surface of the ceramic plate opposite to the first surface, and a through hole connecting the first recessed portion and the second recessed portion, and the ceramic substrate further comprising a metal member disposed continuously in the first recessed portion, the second recessed portion, and the through hole, the metal member comprising a protruding portion having an upper surface, the upper surface protruding with respect to the first surface; and
a covering member being in contact with an other part of an upper surface of the metal member other than the upper surface of the protruding portion and at least a part of the first surface of the ceramic plate, wherein
a surface roughness Ra of the other part of the upper surface of the metal member and the at least a part of the first surface of the ceramic plate is equal to or greater than 350 nm.

12. The wiring substrate according to claim 11, wherein a surface roughness Ra of the upper surface of the protruding portion is in a range from 10 nm to 300 nm.

13. The wiring substrate according to claim 11,
wherein, in a cross-sectional view in a thickness direction of the wiring substrate, the protruding portion has a shape in which a width of the protruding portion continuously increases from the upper surface of the protruding portion toward a lower surface of the protruding portion, and
wherein, in the cross-sectional view in the thickness direction of the wiring substrate, a line forming a side of the protruding portion extending from the upper surface of the protruding portion toward the lower surface of the protruding portion is a curved line.

14. The wiring substrate according to claim 11, wherein a maximum diameter of the metal member disposed in the first recessed portion when viewed in plan view is greater than a maximum diameter of the metal member disposed in the through hole when viewed in plan view.

15. The wiring substrate according to claim 11, wherein an area of the upper surface of the protruding portion is smaller than an area of a lower surface of the protruding portion.

16. The wiring substrate according to claim 11, wherein a center of gravity of the upper surface of the protruding portion and a center of gravity of a lower surface of the protruding portion are located at different positions.

17. The wiring substrate according to claim 11, wherein a thickness of the ceramic plate is in a range from 50 μm to 400 μm.

18. The wiring substrate according to claim 11, wherein each of an average depth of the first recessed portion and an average depth of the second recessed portion is in a range from 1/10 to ⅖ with respect to a thickness of the ceramic plate.
